(19) United States
(12) Patent Application Publication
(10) Pub. No.: US 2022/0403511 A1
(43) Pub. Date: Dec. 22, 2022

(54) SUBSTRATE PROCESSING APPARATUS, EXHAUST DEVICE AND METHOD OF MANUFACTURING SEMICONDUCTOR DEVICE

(71) Applicant: Kokusai Electric Corporation, Tokyo (JP)

(72) Inventors: Hirohisa YAMAZAKI, Toyama-shi (JP); Kenichi SUZAKI, Toyama-shi (JP); Yoshimasa NAGATOMI, Toyama-shi (JP)

(73) Assignee: Kokusai Electric Corporation, Tokyo (JP)

(21) Appl. No.: 17/898,760

(22) Filed: Aug. 30, 2022

Related U.S. Application Data
(63) Continuation of application No. PCT/JP2021/010402, filed on Mar. 15, 2021.

(30) Foreign Application Priority Data
Mar. 18, 2020 (JP) 2020-048503

(51) Int. Cl. C23C 16/44; C23C 16/40; C23C 16/52; H01J 37/32

(52) U.S. Cl. CPC C23C 16/4412; C23C 16/40; C23C 16/52; H01J 37/3244; H01J 37/32844; H01L 21/02189

(57) ABSTRACT

Provided is a technique including: a processing chamber that processes a substrate; a first gas supplier that supplies a metal-containing gas into the processing chamber; a second gas supplier that supplies a first oxygen-containing gas into the processing chamber; and an exhauster including a gas exhaust pipe and a trap that collects a component of the metal-containing gas contained in an exhaust gas using plasma, the exhauster discharging the exhaust gas from the processing chamber.

### CROSS-REFERENCE TO RELATED APPLICATION

This application is a Bypass Continuation application of PCT International Application No. PCT/JP2021/010402, filed on Mar. 15, 2021, the disclosure of which is incorporated herein in its entirety by reference.

### BACKGROUND

### Field

The present disclosure relates to a substrate processing apparatus, an exhaust device, and a method of manufacturing a semiconductor device.

### Description of the Related Art

In a film-forming process of a semiconductor manufacturing apparatus, various liquid sources are used. In the film-forming process, a film-forming source vaporized by a method such as CVD or ALD is supplied to a reaction chamber and discharged to a removing device by a vacuum pump through exhaust piping. In the process, various obstacles such as liquefaction of the film-forming source, thermal decomposition, and generation of a by-product due to a film-forming reaction may occur depending on material properties of the film-forming source.

In particular, in the vacuum pump, an internal rotor mechanism may be stopped due to deposition of a by-product, and therefore a trap mechanism that traps the film-forming source may be disposed between the reaction chamber and the vacuum pump. However, the trap mechanism has a complicated structure to easily trap the film-forming source, and tends to decrease exhaust conductance.

### SUMMARY

As described above, if the exhaust conductance is increased to dispose the trap mechanism between the reaction chamber and the vacuum pump for collecting the liquid source, the by-product, and the like, collection efficiency is decreased. On the contrary, if the exhaust conductance is decreased to increase the collection efficiency, pump exhaust performance is decreased. That is, there is a contradictory relationship. Therefore, there is a problem that sufficient collection efficiency cannot be obtained for the liquid source, or exhaust conductance has a small value.

An object of the present disclosure is to provide a technique for suppressing a decrease in collection efficiency and a decrease in pump exhaust performance.

One aspect of the present disclosure provides

a technique including:

a processing chamber that processes a substrate;

a first gas supplier that supplies a metal-containing gas into the processing chamber;

a second gas supplier that supplies an oxygen-containing gas into the processing chamber; and

an exhauster including a gas exhaust pipe and a trap that collects a component of the metal-containing gas contained in an exhaust gas using plasma, the exhauster discharging the exhaust gas from the processing chamber.

### BRIEF DESCRIPTION OF THE DRAWINGS

FIG. 1 is a schematic longitudinal cross-sectional view for explaining a substrate processing apparatus suitably used in an embodiment of the present disclosure.

FIG. 2 is a vertical cross-sectional view taken along line A-A in FIG. 1.

FIG. 3 is a schematic longitudinal cross-sectional view for explaining a trap suitably used in the embodiment of the present disclosure.

FIG. 4 is a diagram illustrating a configuration of a controller suitably used in the embodiment of the present disclosure.

FIG. 5 is a flowchart for explaining a process of manufacturing a metal oxide film using a substrate processing apparatus according to a preferred embodiment of the present disclosure.

FIG. 6 is a timing chart for explaining a process of manufacturing a metal oxide film using the substrate processing apparatus according to the preferred embodiment of the present disclosure.

### DETAILED DESCRIPTION

A configuration of substrate processing apparatus will be described with reference to the drawings. However, in the following description, the same components are denoted by the same reference numerals, and repeated description may be omitted. Note that, to make description clearer, the drawings may be schematically illustrated in the width, thickness, shape, and the like of each part as compared with an actual aspect. However, the illustration is only an example and does not limit the construe of the present disclosure.

Hereinafter, a substrate processing apparatus according to a preferred embodiment of the present disclosure will be described with reference to the drawings. As an example, the substrate processing apparatus is configured as a semiconductor manufacturing apparatus that performs a film-forming step serving as a substrate processing step in a method of manufacturing an integrated circuit (IC) serving as a semiconductor device.

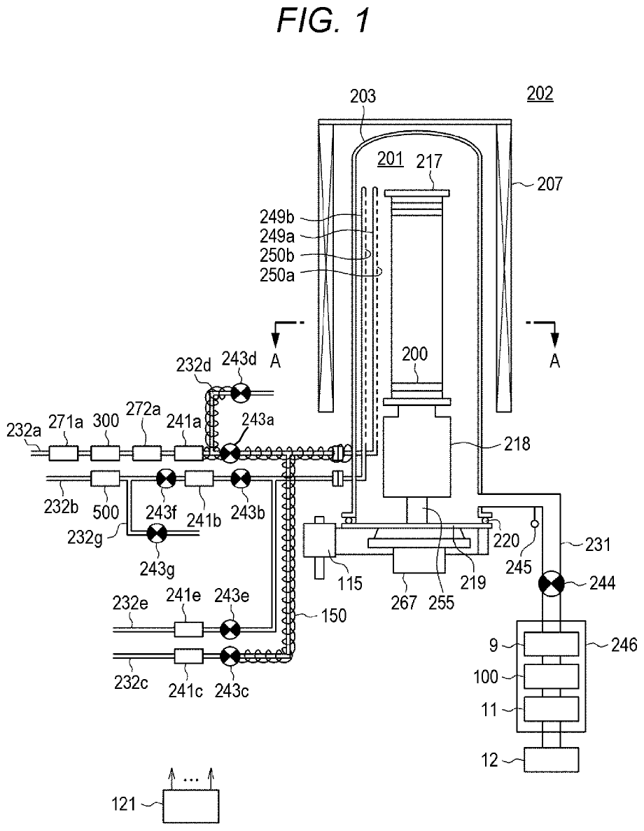

As illustrated in FIG. 1, a processing furnace 202 included in the substrate processing apparatus includes a heater 207 serving as a heating means (heating mechanism). The heater 207 has a cylindrical shape, and is vertically installed by being supported by a heater base (not illustrated) serving as a holding plate. Inside the heater 207, a reaction tube 203 constituting a reaction vessel (processing vessel) concentrically with the heater 207 is disposed.

Below the reaction tube 203, a seal cap 219 serving as a furnace opening lid capable of airtightly closing a lower end opening of the reaction tube 203 is disposed. The seal cap 219 abuts against a lower end of the reaction tube 203 from a lower side in the vertical direction. On an upper surface of the seal cap 219, an O-ring 220 serving as a seal member abutting against the lower end of the reaction tube 203 is disposed. On a side of the seal cap 219 opposite to the processing chamber 201, a rotation mechanism 267 that rotates a boat 217 serving as a substrate supporter is disposed.

A rotation shaft 255 of the rotation mechanism 267 penetrates the seal cap and is connected to the boat 217, and is configured to rotate a wafer 200 serving as a substrate by rotating the boat 217. The seal cap 219 is configured to be raised and lowered in the vertical direction by a boat elevator 115 serving as a raising and lowering mechanism disposed outside the reaction tube 203, and this makes it possible to load the boat 217 into the processing chamber 201 and to unload the boat 217 from the processing chamber 201.

The boat 217 is erected on the seal cap 219 via a quartz cap 218 serving as a heat insulator. The quartz cap 218 is made of, for example, a heat-resistant material such as quartz or silicon carbide, functions as a heat insulator, and serves as a holder that holds the boat. The boat 217 is made of, for example, a heat-resistant material such as quartz or silicon carbide, and is configured such that a plurality of the wafers 200 is aligned in a horizontal posture with their centers aligned with each other and is supported in multiple stages in a tube axis direction.

In the processing chamber 201, a nozzle 249a and a nozzle 249b are disposed in a lower portion of the reaction tube 203 to penetrate the reaction tube 203. A gas supply pipe 232a and a gas supply pipe 232b are connected to the nozzle 249a and the nozzle 249b, respectively. As described above, in the reaction tube 203, the two nozzles 249a and 249b and the two gas supply pipes 232a and 232b are disposed such that a plurality of types of gases can be supplied into the processing chamber 201. As described later, for example, inert gas supply pipes 232c and 232e are connected to the gas supply pipe 232a and the gas supply pipe 232b, respectively.

In the gas supply pipe 232a, in order from an upstream side, a vaporizer 271a that is a vaporizing device (vaporizing means) and vaporizes a liquid source to generate a vaporized gas serving as a source gas, a mist filter 300, a gas filter 272a, a mass flow controller (MFC) 241a that is a flow rate controller, and a valve 243a that is an on-off valve are disposed. By opening the valve 243a, a vaporized gas generated in the vaporizer 271a is supplied into the processing chamber 201 via the nozzle 249a.

To the gas supply pipe 232a, a vent line 232d connected to a gas exhaust pipe 231 described later is connected between the MFC 241a and the valve 243a. In the vent line 232d, a valve 243d that is an on-off valve is disposed. When a source gas described later is not supplied to the processing chamber 201, the source gas is supplied to the vent line 232d via the valve 243d.

By closing the valve 243a and opening the valve 243d, it is possible to stop supply of a vaporized gas into the processing chamber 201 while continuing generation of the vaporized gas in the vaporizer 271a. It takes a predetermined time to stably generate the vaporized gas, but supply and stop of the vaporized gas into the processing chamber 201 can be switched therebetween in a very short time by a switching operation between the valve 243a and the valve 243d.

Furthermore, to the gas supply pipe 232a, an inert gas supply pipe 232c is connected on a downstream side of the valve 243a. In the inert gas supply pipe 232c, in order from an upstream side, an MFC 241c that is a flow rate controller and a valve 243c that is an on-off valve are disposed. To the gas supply pipe 232a, the inert gas supply pipe 232c, and the vent line 232d, a heater 150 is attached to prevent re-liquefying.

The above-described nozzle 249a is connected to a distal end of the gas supply pipe 232a. The nozzle 249a is disposed in an arc-shaped space between an inner wall of the reaction tube 203 and the wafers 200 to rise upward in a stacking direction of the wafers 200 from a lower portion of the inner wall of the reaction tube 203 to an upper portion thereof along the inner wall. The nozzle 249a is configured as an L-shaped long nozzle.

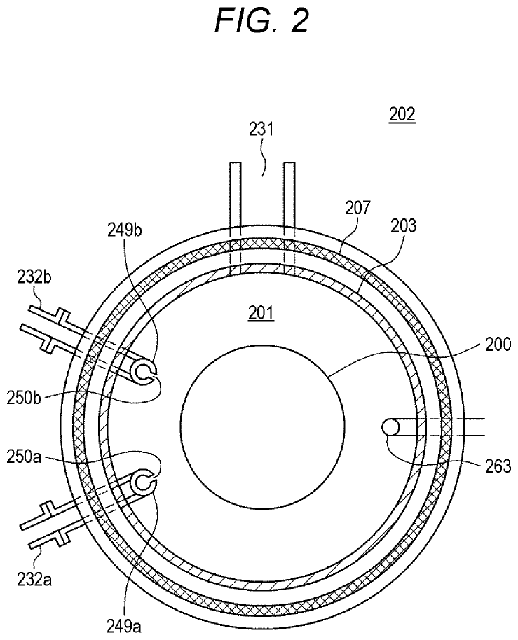

A gas supply hole 250a that supplies gas is disposed on a side surface of the nozzle 249a. As illustrated in FIG. 2, the gas supply hole 250a is opened to face the center of the reaction tube 203. A plurality of the gas supply holes 250a are formed from a lower portion of the reaction tube 203 to an upper portion thereof, each have the same opening area, and are formed at the same opening pitch.

The gas supply pipe 232a, the vent line 232d, the valves 243a and 243d, the MFC 241a, the vaporizer 271a, the mist filter 300, the gas filter 272a, and the nozzle 249a mainly constitute a first processing gas supply system. At least the nozzle 249a constitutes a first gas supplier. The inert gas supply pipe 232c, the MFC 241c, and the valve 243c mainly constitute a first inert gas supply system.

In the gas supply pipe 232b, in order from an upstream side, an ozonizer 500 that generates an ozone (O₃) gas, a valve 243f, an MFC 241b that is a flow rate controller, and a valve 243b that is an on-off valve are disposed. An upstream side of the gas supply pipe 232b is connected to, for example, an oxygen gas supply source (not illustrated) that supplies an oxygen (O₂) gas.

An O₂ gas supplied to the ozonizer 500 becomes an O₃ gas) serving as an oxygen-containing gas in the ozonizer 500, and is supplied into the processing chamber 201. To the gas supply pipe 232b, a vent line 232g connected to a gas exhaust pipe 231 described later is connected between the ozonizer 500 and the valve 243f. In the vent line 232g, a valve 243g that is an on-off valve is disposed. When an O₃ gas) described later is not supplied to the processing chamber 201, the source gas is supplied to the vent line 232g via the valve 243g. By closing the valve 243f and opening the valve 243g, it is possible to stop supply of an O₃ gas) into the processing chamber 201 while continuing generation of the O₃ gas) by the ozonizer 500.

It takes a predetermined time to stably purify the O₃ gas) serving as an oxygen-containing gas, but supply and stop of the O₃ gas) into the processing chamber 201 can be switched therebetween in a very short time by a switching operation between the valve 243f and the valve 243g. Furthermore, to the gas supply pipe 232b, an inert gas supply pipe 232e is connected on a downstream side of the valve 243b. In the inert gas supply pipe 232e, in order from an upstream side, an MFC 241e that is a flow rate controller and a valve 243e that is an on-off valve are disposed.

The above-described nozzle 249b is connected to a distal end of the gas supply pipe 232b. The nozzle 249b is disposed in an arc-shaped space between an inner wall of the reaction tube 203 and the wafers 200 to rise upward in a stacking direction of the wafers 200 from a lower portion of the inner wall of the reaction tube 203 to an upper portion thereof along the inner wall. The nozzle 249b is configured as an L-shaped long nozzle.

A gas supply hole 250b that supplies gas is disposed on a side surface of the nozzle 249b. As illustrated in FIG. 2, the gas supply hole 250b is opened to face the center of the reaction tube 203. A plurality of the gas supply holes 250b are formed from a lower portion of the reaction tube 203 to an upper portion thereof, each have the same opening area, and are formed at the same opening pitch.

The gas supply pipe 232b, the vent line 232g, the ozonizer 500, the valves 243f, 243g, and 243b, the MFC 241b, and the nozzle 249b mainly constitute a second processing gas supply system. At least the nozzle 249b constitutes a second gas supplier. The inert gas supply pipe 232e, the MFC 241e, and the valve 243e mainly constitute a second inert gas supply system.

From the gas supply pipe 232a, for example, a source gas serving as a metal-containing gas is supplied as a first source gas into the processing chamber 201 via the vaporizer 271a, the mist filter 300, the gas filter 272a, the MFC 241a, the valve 243a, and the nozzle 249a.

A gas containing an oxygen (O) atom (oxygen-containing gas) is supplied to the gas supply pipe 232b, becomes, for example, an O₃ gas) (first oxygen-containing gas) in the ozonizer 500, and is supplied as an oxidizing gas (oxidizing agent) into the processing chamber 201 via the valve 243f, the MFC 241b, and the valve 243b. It is also possible to supply an O₂ gas as an oxidizing gas (first oxygen-containing gas) into the processing chamber 201 without generating an O₃ gas) in the ozonizer 500.

Inert gases are supplied from the inert gas supply pipes 232c and 232e to the processing chamber 201 via the MFCs 241c and 241e, the valves 243c and 243e, the gas supply pipes 232a and 232b, and the nozzles 249a and 249b, respectively.

In the reaction tube 203, an exhaust pipe 231 that discharges an atmosphere of the processing chamber 201 is disposed. To the exhaust pipe 231, a vacuum exhaust device 246 is connected via a pressure sensor 245 serving as a pressure detector that detects a pressure of the processing chamber 201 and an auto pressure controller (APC) valve 244 serving as a pressure regulator, which is configured to be able to perform vacuum exhaust such that a pressure in the processing chamber 201 is a predetermined pressure (vacuum degree).

Note that the APC valve 244 is an on-off valve that can open and close a valve to vacuum-exhaust the processing chamber 201 and stop vacuum exhaust, and can further adjust the degree of valve opening to adjust a pressure. The gas exhaust pipe 231, the APC valve 244, the vacuum exhaust device 246, and the pressure sensor 245 mainly constitute an exhaust system.

The vacuum exhaust device 246 is configured by connecting a mechanical booster pump (MBP) 9 serving as an auxiliary pump, a trap mechanism 10 that collects a film-forming source and a by-product, and a dry pump (DP) 11 serving as a pump in this order from the processing chamber 201 side. To the dry pump 11, a removing device 12 is connected. Since the dry pump 11 compresses an atmosphere, compression heat is generated. Therefore, an organometallic source may react, and a product may adhere. On the other hand, since the mechanical booster pump 9 operates in a place close to the processing chamber 201 and in a condition close to vacuum as compared with the dry pump 11, compression heat is less likely to be generated. Therefore, the organometallic source passes through the mechanical booster pump 9 without reacting. Therefore, the trap mechanism 10 is preferably disposed between the mechanical booster pump 9 and the dry pump 11. Note that the mechanical booster pump 9 may be disposed between the trap mechanism 10 and the dry pump 11. At least the gas exhaust pipe 231, the mechanical booster pump 9, the trap 100, and the dry pump 11 constitute an exhauster (exhaust device).

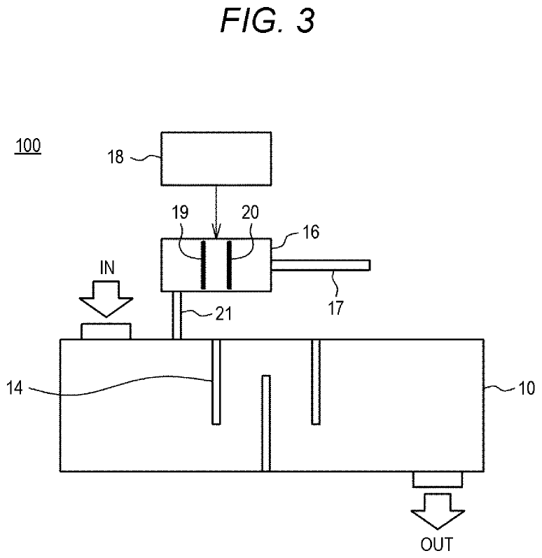

As illustrated in FIG. 3, the trap 100 includes the trap mechanism 10 that collects a metal-containing gas contained in an exhaust gas, a plasma generator 16 that generates plasma, a gas supply pipe (gas supplier) 17 that supplies an oxygen-containing gas to the plasma generator 16, a high-frequency power supply 18 that supplies high-frequency power to the plasma generator 16, and a gas supply pipe (gas supplier) 21 that supplies an active species activated by the plasma generator 16 to the trap mechanism 10. The trap mechanism 10 causes a film-forming source and a by-product to adhere to a trap fin 14 by radical oxidation using an oxygen plasma system while the film-forming source is flowing, and collects the film-forming source and the by-product. Here, a material of the trap fin 14 is preferably stainless steel, for example, SUS 316.

When a metal-containing gas is supplied into the processing chamber 201, an oxygen (O₂) gas (H₂O or O₃ may be used) is supplied as an oxygen-containing gas (second oxygen-containing gas) to the plasma generator 16 from the gas supply pipe 17 serving as a third gas supplier, and high-frequency power (for example, high-frequency power of 27.12 MHz within a range of 0.5 KW or more and 3.5 KW or less) is applied from the high-frequency power supply 18. At this time, plasma is generated between an electrode 19 connected to the high-frequency power supply 18 and an electrode 20 connected to the ground that is a reference potential, and an oxygen gas excited (activated) to a plasma state (active species activated to a plasma state) is generated. This means for generating plasma is capacitively coupled plasma (CCP).

An exhaust gas containing a metal-containing gas (a metal-containing gas component, a component of metal-containing gas) that has not reacted or has contributed to formation of the metal-containing layer, the exhaust gas being discharged from the processing chamber 201, is supplied into the trap mechanism 10. When the active species activated by the plasma generator 16 is supplied into the trap mechanism 10 via the gas supply pipe 21, the active species reacts with the metal-containing gas component (the component of metal-containing gas), and a product adheres to the trap fin 14, whereby the metal-containing gas component that has not reacted or has contributed to formation of the metal-containing layer is removed from the exhaust gas. The exhaust gas from which the metal-containing gas component that has not reacted or has contributed to formation of the metal-containing layer has been removed is discharged from Out of the trap mechanism 10 to the dry pump 11. This makes it possible to prevent deposition of a product in the dry pump 11.

As a means for generating plasma, any method may be used. For example, inductively coupled plasma (abbreviated as IPC), electron cyclotron resonance plasma (abbreviated as ECR plasma), helicon wave excited plasma (abbreviated as HWP), or surface wave plasma (abbreviated as SWP) may be used.

The first oxygen-containing gas used in the film-forming step and the second oxygen-containing gas used in the trap 100 may be the same gas or different gases. In a case of the same gas, a large amount of O₃ is required in the film-forming step, and it is difficult to ensure the amount used in the trap 100. Therefore, by using O₂ for plasma as a different gas, consumption of O₃ can be reduced. If the amount to be used in the film-forming step and the amount to be used in the trap can be ensured, when O₃ is used as the same gas, an ozonizer can be commonly used, and therefore a device configuration can be simplified.

The temperature of the exhaust gas is not particularly required to be controlled, but the exhaust piping may be heated to heat the exhaust gas. By heating the exhaust gas, the organometallic source more easily reacts with the oxygen plasma.

A temperature sensor 263 serving as a temperature detector is disposed in the reaction tube 203, which is configured such that the temperature in the processing chamber 201 has a desired temperature distribution by adjusting the degree of energization to the heater 207 based on temperature information detected by the temperature sensor 263. The temperature sensor 263 is formed in an L shape similarly to the nozzles 249a and 249b, and is disposed along an inner wall of the reaction tube 203.

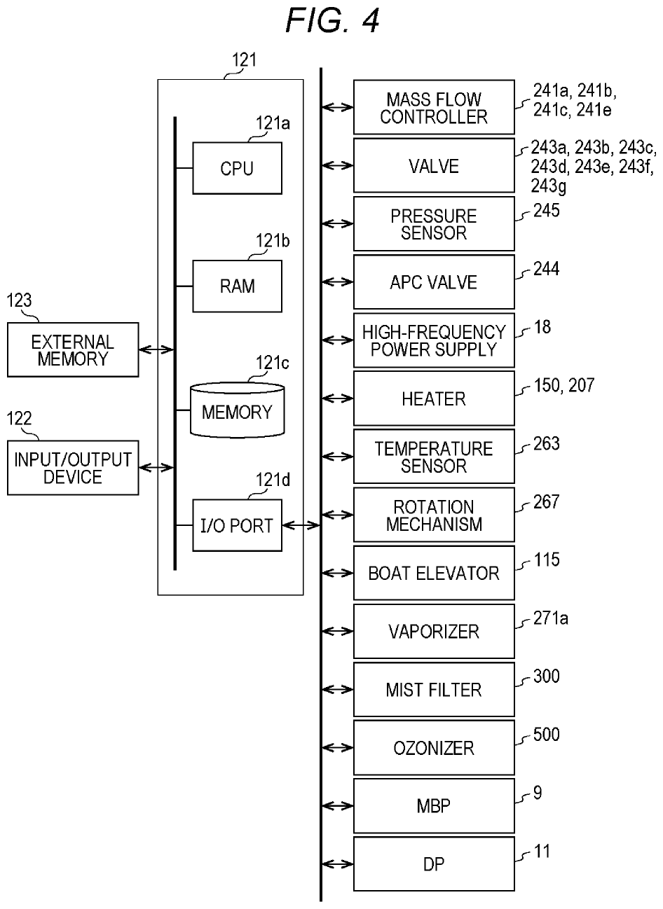

As illustrated in FIG. 4, a controller 121 that is a control means is configured as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus. To the controller 121, an input/output device 122 configured as, for example, a touch panel is connected. In addition, to the controller 121, an external memory (storage medium) 123 storing a program described later can be connected.

The memory 121c includes, for example, a flash memory and a hard disk drive (HDD). In the memory 121c, a control program that controls an operation of the substrate processing apparatus, a process recipe in which procedures and conditions of substrate processing described later are described, and the like are readably stored. In addition, by storing the control program, the process recipe, and the like in the external memory 123 and connecting the external memory 123 to the controller 121, the control program, the process recipe, and the like can be stored in the memory 121c.

Note that the process recipe is a combination formed to cause the controller 121 to execute procedures in a substrate processing step described later to obtain a predetermined result, and functions as a program. Hereinafter, the process recipe, the control program, and the like are also collectively and simply referred to as a program.

In the present specification, the term “program” may include only a process recipe alone, only a control program alone, or both. The RAM 121b is configured as a memory area (work area) in which a program, data, and the like read by the CPU 121a are temporarily stored.

The I/O port 121d is connected to the MFCs 241a, 241b, 241c, and 241e, the valves 243a, 243b, 243c, 243d, 243e, 243f, and 243g, the vaporizer 271a, the mist filter 300, the ozonizer 500, the pressure sensor 245, the APC valve 244, the mechanical booster pump 9, the dry pump 11, the high-frequency power supply 18, the heaters 150 and 207, the temperature sensor 263, the boat rotation mechanism 267, the boat elevator 115, and the like.

The CPU 121a is configured to read a control program from the memory 121c, to execute the control program, and to read a process recipe from the memory 121c in response to, for example, an input of an operation command from the input/output device 122.

According to the read process recipe, the CPU 121a performs control, for example, for flow rate adjustment operations of various gases by the MFCs 241a, 241b, 241c, and 241e, opening and closing operations of the valves 243a, 243b, 243c, 243d, 243e, 243f, and 243g, opening and closing of the APC valve 244, a pressure adjustment operation based on the pressure sensor 245, a temperature adjustment operation of the heater 150, a temperature adjustment operation of the heater 207 based on the temperature sensor 263, operations of the vaporizer 271a, the mist filter 300, and the ozonizer 500, start and stop of the mechanical booster pump 9, the dry pump 11, and the high-frequency power supply 18, a rotation speed adjustment operation of the boat rotation mechanism 267, a raising and lowering operation of the boat elevator 115, and the like.

(2) Substrate Processing Step

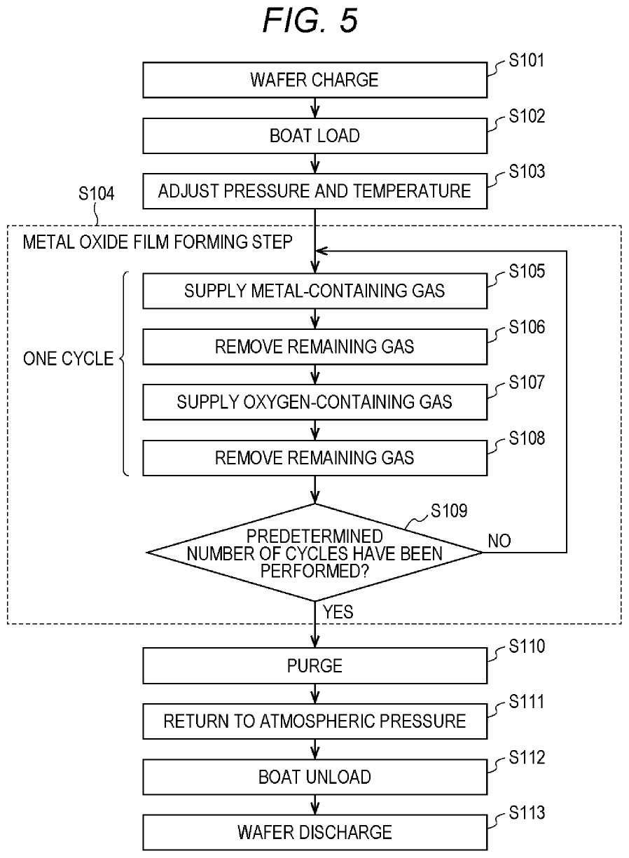

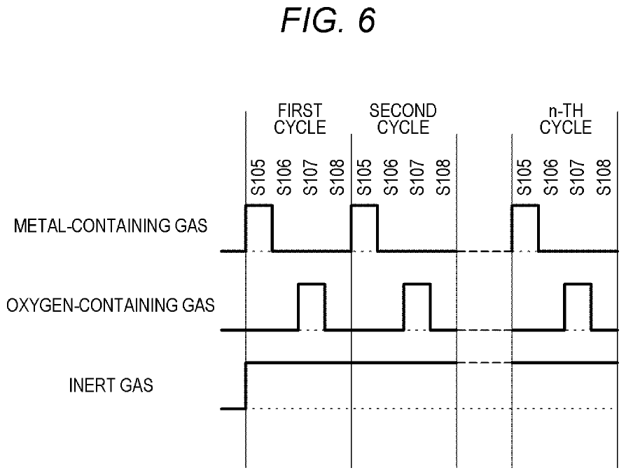

Next, as a step of a semiconductor device manufacturing process using the processing furnace of the above-described substrate processing apparatus, a sequence example of forming an insulating film on a substrate will be described with reference to FIGS. 5 and 6. Note that, in the following description, operations of the units constituting the substrate processing apparatus are controlled by the controller 121.

Examples of a film forming method include a method of simultaneously supplying a plurality of types of gases containing a plurality of elements constituting a film to be formed, and a method of alternately supplying a plurality of types of gases containing a plurality of elements constituting a film to be formed.

First, when the boat 217 is charged with the plurality of wafers 200 (wafer charge) (see step S101 in FIG. 5), the boat 217 supporting the plurality of wafers 200 is lifted and loaded into the processing chamber 201 (boat load) by the boat elevator 115 (see step S102 in FIG. 5). In this state, the seal cap 219 is in a state of airtightly sealing a lower end of the reaction tube 203 via the O-ring 220.

The processing chamber 201 is vacuum-exhausted by the vacuum exhaust device 246 to have a desired pressure (degree of vacuum). At this time, a pressure in the processing chamber 201 is measured by the pressure sensor 245, and the APC valve 244 is feedback-controlled based on the measured pressure (pressure adjustment) (see step S103 in FIG. 5).

The processing chamber 201 is heated by the heater 207 to have a desired temperature. At this time, the degree of energization to the heater 207 is feedback-controlled based on temperature information detected by the temperature sensor 263 such that the processing chamber 201 has a desired temperature distribution (temperature adjustment) (see step S103 in FIG. 5). Subsequently, the boat 217 is rotated by the rotation mechanism 267, whereby the wafers 200 are rotated.

Next, an insulating film forming step of forming a metal oxide film that is an insulating film (see step S104 in FIG. 5) is performed by supplying a metal-containing gas and an oxygen-containing gas to the processing chamber 201. In the insulating film forming step, the following four steps are sequentially executed.

(Insulating Film Forming Step)

<Step S105>

In step S105 (see FIGS. 5 and 6), first, a metal-containing gas is caused to flow. By opening the valve 243a of the gas supply pipe 232a and closing the valve 243d of the vent line 232d, a metal-containing gas is caused to flow in the gas supply pipe 232a via the vaporizer 271a, the mist filter 300, and the gas filter 272a. A flow rate of the metal-containing gas flowing in the gas supply pipe 232a is adjusted by the MFC 241a. The metal-containing gas whose flow rate has been adjusted is discharged from the gas exhaust pipe 231 while being supplied from the gas supply hole 250a of the nozzle 249a to the processing chamber 201. At this time, the valve 243c is simultaneously opened to cause an inert gas to flow in the gas supply pipe 232c. A flow rate of the inert gas flowing in the gas supply pipe 232c is adjusted by the MFC 241c. The inert gas whose flow rate has been adjusted is discharged from the gas exhaust pipe 231 while being supplied to the processing chamber 201 together with the metal-containing gas. By supplying the metal-containing gas to the processing chamber 201, the metal-containing gas reacts with the wafer 200, and a metal-containing layer is formed on the wafer 200.

At this time, the APC valve 244 is appropriately adjusted to set a pressure in the processing chamber 201 to, for example, a pressure within a range of 50 to 400 Pa. A supply flow rate of the metal-containing gas controlled by the MFC 241a is set to, for example, a flow rate within a range of 0.1 to 0.5 g/min. Time during which the wafers 200 are exposed to the metal-containing gas, that is, a gas supply time (irradiation time) is set to, for example, a time within a range of 30 to 240 seconds. At this time, the temperature of the heater 207 is set to a temperature at which the temperature of the wafers 200 is, for example, within a range of 150 to 250° C.

<Step S106>

In step S106 (see FIGS. 5 and 6), after the metal-containing layer is formed, the valve 243a is closed and the valve 243d is opened to stop supply of the metal-containing gas to the processing chamber 201, and the metal-containing gas is caused to flow to the vent line 232d. At this time, with the APC valve 244 of the gas exhaust pipe 231 open, the processing chamber 201 is vacuum-exhausted by the vacuum exhaust device 246, and a metal-containing gas that has not reacted or has contributed to formation of the metal-containing layer, the metal-containing gas remaining in the processing chamber 201, is removed from the processing chamber 201. Note that, at this time, supply of the inert gas to the processing chamber 201 is maintained with the valve 243c open. As a result, an effect of removing the metal-containing gas that has not reacted or has contributed to formation of the metal-containing layer, the metal-containing gas remaining in the processing chamber 201, from the processing chamber 201 is enhanced. An exhaust gas containing the metal-containing gas (metal-containing gas component) discharged from the processing chamber 201 is supplied into the trap mechanism 10. The metal-containing gas component supplied into the trap mechanism 10 reacts with an active species, and a product adheres to the trap fin 14, whereby the metal-containing gas component that has not reacted or has contributed to formation of the metal-containing layer is removed from the exhaust gas.

<Step S107>

In step S107 (see FIGS. 5 and 6), after the gas remaining in the processing chamber 201 is removed, an oxygen-containing gas is caused to flow in the gas supply pipe 232b. For example, an O₂ gas flowing in the gas supply pipe 232b becomes an O₃ gas) by the ozonizer 500. By opening the valve 243f and the valve 243b of the gas supply pipe 232b and closing the valve 243g of the vent line 232g, a flow rate of the oxygen-containing gas (second oxygen-containing gas) flowing in the gas supply pipe 232b is adjusted by the MFC 241b, and the oxygen-containing gas is discharged from the gas exhaust pipe 231 while being supplied from the gas supply hole 250b of the nozzle 249b to the processing chamber 201. At this time, the valve 243e is simultaneously opened to cause an inert gas to flow in the inert gas supply pipe 232e. The inert gas is discharged from the gas exhaust pipe 231 while being supplied to the processing chamber 201 together with the oxygen-containing gas. By supplying the oxygen-containing gas to the processing chamber 201, the metal-containing layer formed on the wafer 200 reacts with the oxygen-containing gas to form a metal oxide layer.

When the oxygen-containing gas is caused to flow, the APC valve 244 is appropriately adjusted to set a pressure in the processing chamber 201 to, for example, a pressure within a range of 50 to 400 Pa. A supply flow rate of the O₃ gas) controlled by the MFC 241b is set to, for example, a flow rate within a range of 10 to 20 slm. Time during which the wafers 200 are exposed to the oxygen-containing gas, that is, a gas supply time (irradiation time) is set to, for example, a time within a range of 60 to 300 seconds. At this time, the temperature of the heater 207 is set to a temperature at which the temperature of the wafers 200 is, for example, within a range of 150 to 250° C. as in step S105.

<Step S108>

In step S108 (see FIGS. 5 and 6), the valve 243b of the gas supply pipe 232b is closed and the valve 243g is opened to stop supply of the oxygen-containing gas (second oxygen-containing gas) to the processing chamber 201, and the oxygen-containing gas is caused to flow to the vent line 232g. At this time, with the APC valve 244 of the gas exhaust pipe 231 open, the processing chamber 201 is vacuum-exhausted by the vacuum exhaust device 246, and an oxygen-containing gas that has not reacted or has contributed to oxidation, the oxygen-containing gas remaining in the processing chamber 201, is removed from the processing chamber 201. Note that, at this time, supply of the inert gas to the processing chamber 201 is maintained with the valve 243e open. As a result, an effect of removing the oxygen-containing gas that has not reacted or has contributed to oxidation, the oxygen-containing gas remaining in the processing chamber 201, from the processing chamber 201 is enhanced.

By performing at least one cycle, which is composed of the above-described steps S105 to S108 (step S109), a metal oxide film having a predetermined film thickness can be formed on the wafer 200. Note that the above-described cycle is preferably repeatedly performed a plurality of times. As a result, a desired metal oxide film is formed on the wafer 200.

After the metal oxide film is formed, the valve 243a of the gas supply pipe 232a is closed, the valve 243b of the gas supply pipe 232b is closed, the valve 243c of the inert gas supply pipe 232c is opened, and the valve 243e of the inert gas supply pipe 232e is opened to cause an inert gas to flow in the processing chamber 201. The inert gas acts as a purge gas, whereby the processing chamber 201 is purged with the inert gas, and a gas remaining in the processing chamber 201 is removed from the processing chamber 201 (purge, step S110). Thereafter, an atmosphere in the processing chamber 201 is replaced with the inert gas, and a pressure in the processing chamber 201 is returned to a normal pressure (return to atmospheric pressure, step S111).

Thereafter, the seal cap 219 is lowered by the boat elevator 115, a lower end of a manifold 209 is opened, and the processed wafers 200 are unloaded from the lower end of the manifold 209 to the outside of the reaction tube 203 in a state of being held by the boat 217 (boat unload, step S112). Thereafter, the processed wafers 200 are taken out from the boat 217 (wafer discharge, step S112).

In addition, the present disclosure can also be achieved, for example, by changing a process recipe of an existing substrate processing apparatus. When a process recipe is changed, the process recipe according to the present disclosure can be installed in an existing substrate processing apparatus via a telecommunication line or a recording medium in which the process recipe according to the present disclosure is recorded, or a process recipe itself of an existing substrate processing apparatus can be changed to the process recipe according to the present disclosure by operating an input/output device of the existing substrate processing apparatus.

For example, in the above-described embodiment, as the metal-containing gas, for example, a Zr(O-tBu)₄ gas, a tetrakis(dimethylamino)zirconium (Zr(NMe₂)₄) (TDMAZ) gas, a tetrakis(ethylmethylamino)zirconium (Zr[N(CH₃)C₂H₅]₄) (TEMAZ) gas, a tetrakis(diethylamino)zirconium (Zr(NETt₂)₄) (TDEAZ) gas, or a Zr(MMP)₄ gas can be used. As the source gas, for example, an organometallic source gas containing a metal element and carbon, such as a trimethylaluminum (Al(CH₃)₃, abbreviated as TMA) gas can also be used. As a reactant gas, a gas similar to that used in the above-described embodiment can be used.

As the oxygen-containing gas (first oxygen-containing gas) used in the film-forming step, an O₂ gas, an H₂O gas, an O₃ gas), or the like can be used.

As the oxygen-containing gas (second oxygen-containing gas) used in the trap 100, an O₂ gas, an H₂O gas, an O₃ gas), or the like can be used.

As the inert gas, a rare gas such as a N₂ gas, an Ar gas, a He gas, a Ne gas, or a Xe gas can be used.

In addition, in the above-described embodiment, an example in which a film is deposited on the wafer 200 has been described. However, the present disclosure is not limited to such an aspect. For example, the present disclosure is also suitably applicable to a case where processing such as oxidizing, diffusing, annealing, or etching is performed on a film or the like formed on the wafer 200.

In addition, the present disclosure is applicable not only to a semiconductor manufacturing apparatus that processes a semiconductor wafer, such as the substrate processing apparatus according to the present embodiment but also to a liquid crystal display (LCD) manufacturing apparatus that processes a glass substrate.

The present disclosure can suppress a decrease in collection efficiency and a decrease in pump exhaust performance.

What is claimed is:

1. A substrate processing apparatus comprising:
a processing chamber configured to process a substrate;
a first gas supplier configured to supply a metal-containing gas into the processing chamber;
a second gas supplier configured to supply a first oxygen-containing gas into the processing chamber; and
an exhauster including a gas exhaust pipe and a trap configured to collect a component of the metal-containing gas contained in an exhaust gas using plasma, the exhauster being configured to discharge the exhaust gas from the processing chamber.

2. The substrate processing apparatus according to claim 1, wherein the trap is disposed between a pump configured to exhaust the processing chamber and an auxiliary pump configured to support the pump.

3. The substrate processing apparatus according to claim 1, wherein the trap includes a trap mechanism configured to collect the component of the metal-containing gas contained in the exhaust gas, a plasma generator configured to generate the plasma, a third gas supplier configured to supply a second oxygen-containing gas to the plasma generator, a high-frequency power supply configured to supply high-frequency power to the plasma generator, and a fourth gas supplier configured to supply a gas from the plasma generator to the trap mechanism.

4. The substrate processing apparatus according to claim 3, wherein the plasma generator activates the second oxygen-containing gas with plasma and supplies the activated second oxygen-containing gas to the trap mechanism via the fourth gas supplier.

5. The substrate processing apparatus according to claim 3, wherein the plasma generator includes an electrode connected to the high-frequency power supply and an electrode connected to the ground that is a reference potential.

6. The substrate processing apparatus according to claim 4, wherein the component of the metal-containing gas is caused to react with the second oxygen-containing gas activated by the plasma generator in the trap mechanism.

7. The substrate processing apparatus according to claim 3, wherein the trap mechanism includes a trap fin to which the component of the metal-containing gas adheres.

8. The substrate processing apparatus according to claim 7, wherein a product generated by a reaction between the component of the metal-containing gas and the second oxygen-containing gas activated by the plasma generator is caused to adhere to the trap fin.

9. The substrate processing apparatus according to claim 7, wherein the trap fin is made of stainless steel.

10. The substrate processing apparatus according to claim 2, wherein the pump is a dry pump, and the auxiliary pump is a mechanical booster pump.

11. The substrate processing apparatus according to claim 3, wherein the first oxygen-containing gas and the second oxygen-containing gas are the same gas.

12. The substrate processing apparatus according to claim 11, wherein the first oxygen-containing gas and the second oxygen-containing gas are ozone.

13. The substrate processing apparatus according to claim 3, wherein the first oxygen-containing gas and the second oxygen-containing gas are different gases.

14. The substrate processing apparatus according to claim 13, wherein the first oxygen-containing gas is oxygen, and the second oxygen-containing gas is ozone.

15. The substrate processing apparatus according to claim 11, comprising an ozonizer configured to generate the ozone.

16. The substrate processing apparatus according to claim 1, comprising a controller configured to control the first gas supplier, the second gas supplier and the exhauster to alternately perform (a) supplying the metal-containing gas from the first gas supplier into the processing chamber and (b) supplying the first oxygen-containing gas from the second gas supplier into the processing chamber, and perform (c) discharging the exhaust gas containing the component of the metal-containing gas after (a) and (d) collecting the component of the metal-containing gas contained in the exhaust gas.

17. An exhaust device comprising:
a gas exhaust pipe; and
a trap configured to collect a component of a metal-containing gas contained in an exhaust gas using an oxygen-containing gas activated with plasma, wherein the exhaust device is configured to discharge the exhaust gas from a processing chamber.

18. A method of manufacturing a semiconductor device, the method comprising:
housing a substrate in a processing chamber of a substrate processing apparatus including: the processing chamber configured to process the substrate; a first gas supplier configured to supply a metal-containing gas into the processing chamber; a second gas supplier configured to supply a first oxygen-containing gas into the processing chamber; and an exhauster including a gas exhaust pipe and a trap configured to collect a component of the metal-containing gas contained in an exhaust gas using plasma, the exhauster being configured to discharge the exhaust gas from the processing chamber;
supplying the metal-containing gas into the processing chamber;
discharging the component of the metal-containing gas from the processing chamber; and
collecting the component of the metal-containing gas by the trap.
